(19) United States
(12) Patent Application Publication
(10) Pub. No.: US 2026/0082944 A1
(43) Pub. Date: Mar. 19, 2026

(54) SEMICONDUCTOR DEVICE AND METHOD FOR MANUFACTURING THE SAME

(71) Applicants: KABUSHIKI KAISHA TOSHIBA, Tokyo (JP); Toshiba Electronic Devices & Storage Corporation, Tokyo (JP)

(72) Inventor: Yoshiki Endo, Kawasaki Kanagawa (JP)

(73) Assignees: KABUSHIKI KAISHA TOSHIBA, Tokyo (JP); Toshiba Electronic Devices & Storage Corporation, Tokyo (JP)

(21) Appl. No.: 19/241,528

(22) Filed: Jun. 18, 2025

(30) Foreign Application Priority Data
Sep. 19, 2024 (JP) 2024-162500

(51) Int. Cl. H01L 23/495; H01L 21/48; H01L 21/56; H01L 23/00; H01L 23/31

(52) U.S. Cl. CPC H10W 70/481; H10W 70/041; H10W 70/415; H10W 74/016; H10W 74/111; H10W 90/811; H10W 72/865; H10W 72/884; H10W 90/736; H10W 90/755

(57) ABSTRACT

According to one embodiment, a semiconductor device includes a semiconductor chip, a first conductor which includes a first portion exposed from a first surface of a sealing resin facing to a first direction, a second portion projecting from a second surface of the sealing resin facing to a second direction, and a bent portion connecting the first portion and the second portion, a second conductor exposed from a third surface of the sealing resin opposed to the first surface and having a thickness in the first direction which is greater than a thickness of the first conductor, a third conductor provided between the semiconductor chip and the first conductor, a first bonding material which bonds the semiconductor chip and the second conductor, a second bonding material which bonds the semiconductor chip and the third conductor, and a third bonding material which bonds the third conductor and the first conductor.

### CROSS-REFERENCE TO RELATED APPLICATION(S)

This application is based upon and claims the benefit of priority from prior Japanese Patent Application No. 2024-162500, filed Sep. 19, 2024, the entire contents of which are incorporated herein by reference.

### FIELD

Embodiment described herein relates generally to a semiconductor device and a method for manufacturing the same.

### BACKGROUND

A semiconductor device such as a power MOSFET implemented on the surface of a printed circuit board is known as a switching element for use in a power conversion device such as a DC-DC converter.

### BRIEF DESCRIPTION OF THE DRAWING(S)

FIG. 1 is a plan view of the top surface of a package of a semiconductor device according to an embodiment.

FIG. 2 is a plan view of the bottom surface of the package of the semiconductor device according to the embodiment.

FIG. 3 is an exploded view showing an example of an internal configuration of the semiconductor device according to the embodiment.

FIG. 4 is a plan view showing an example of a planar layout of semiconductor chips, gate electrodes, and a terminal portion 20b of an emitter electrode included in the semiconductor device according to the embodiment.

FIG. 5 is a sectional view of the semiconductor device taken along line A-A of FIG. 1.

FIG. 6 is a sectional view of the semiconductor device taken along line B-B of FIG. 1.

FIG. 7 is a flowchart showing an example of an assembly process of the semiconductor device according to the embodiment.

FIG. 8 is a sectional view showing an example of a state in which a wire bonding product of the semiconductor device according to the embodiment is set in a mold for molding.

### DETAILED DESCRIPTION

In general, according to one embodiment, a semiconductor device includes a semiconductor chip, a first conductor which includes a first portion exposed from a first surface of a sealing resin facing to a first direction, a second portion projecting from a second surface of the sealing resin facing to a second direction intersecting with the first direction, and a bent portion connecting the first portion and the second portion, a second conductor exposed from a third surface of the sealing resin opposed to the first surface and having a thickness in the first direction which is greater than a thickness of the first conductor, a third conductor provided between the semiconductor chip and the first conductor, a first bonding material which bonds the semiconductor chip and the second conductor, a second bonding material which bonds the semiconductor chip and the third conductor, and a third bonding material which bonds the third conductor and the first conductor.

An embodiment will be described below with reference to the drawings. In the following description, components having the same function and configuration are denoted by a common reference symbol. In addition, the following embodiment exemplifies a device and a method for embodying the technical concepts of the embodiment, and do not specify the materials, shapes, structures, arrangement or the like of the components. The semiconductor device according to the embodiment will be described below.

### 1. Configuration of Semiconductor Device

### 1.1 Planar Configuration of Semiconductor Device

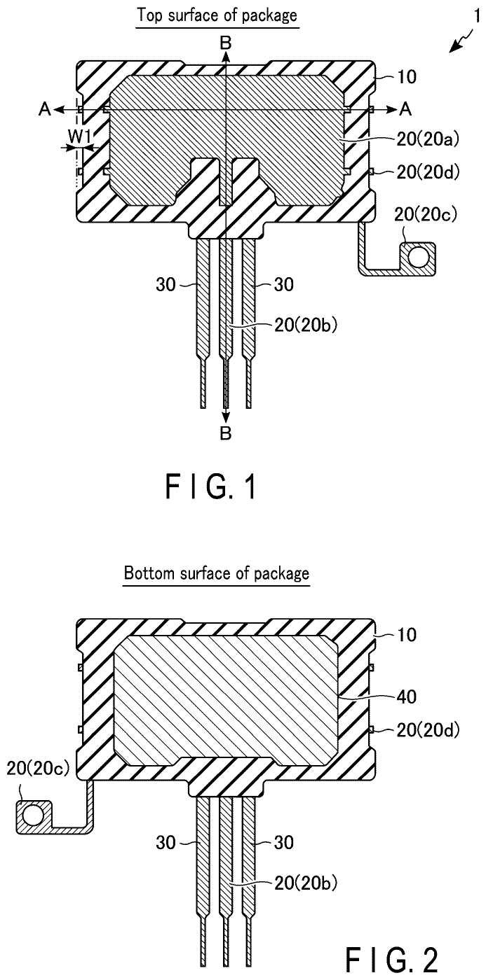

First, an example of a planar configuration of a semiconductor device 1 will be described with reference to FIGS. 1 and 2. FIG. 1 is a plan view of the top surface of a package of the semiconductor device 1. FIG. 2 is a plan view of the bottom surface of the package of the semiconductor device 1.

In the following description, the direction perpendicular to the substrate of a semiconductor chip mounted on the semiconductor device 1 will be denoted as a Z direction, a vertical direction, or a substrate thickness direction. In addition, the two directions perpendicular to each other in the plane perpendicular to the Z direction will be denoted as an X and Y directions. The two surfaces facing to the Z direction of the semiconductor device 1 will be denoted as a package top surface and a package bottom surface. The surface facing to the X or Y direction of the semiconductor device 1 will be denoted as a package side surface.

As shown in FIGS. 1 and 2, the semiconductor device 1 has a substantially rectangular parallelepiped shape, for example. The semiconductor device 1 includes a sealing resin 10, an emitter electrode 20, two gate electrodes 30, and a collector electrode 40. Each of the emitter electrode 20, the gate electrode 30, and the collector electrode 40 has a terminal portion exposed to the outside of the sealing resin 10 (package) as a terminal serving as electrical connection to an external device.

The sealing resin 10 is an insulating member that protects the internal structure of the semiconductor device 1 physically and electrically from outside. The sealing resin 10 forms the outer shape of the semiconductor device 1. For example, a thermosetting epoxy resin is used as the sealing resin 10. Note that the sealing resin 10 may contain a filler such as silicon oxide.

The emitter electrode 20 is connected to another circuit on the top or side surface of the package. In the example shown in FIGS. 1 and 2, the emitter electrode 20 includes an exposed portion 20a, terminal portions 20b and 20c, and a cutting portion 20d. These portions are connected to each other at the inside of the sealing resin 10.

The exposed portion 20a is exposed to the top surface of the package to function as a terminal connected to an external device. The exposed portion 20a also functions as a heat sink. The exposed surface (top surface) of the exposed portion 20a has flatness over the entire surface, for example. The shape of the exposed portion 20a on the top surface of the package is optional.

The terminal portion 20b projects from the central part of the side surface of the package facing to the Y direction (lower side of the drawing sheet) and extends in the Y direction (lower side of the drawing sheet).

The terminal portion 20c projects from an end portion of the side surface of the package facing to the Y direction (lower side of the drawing sheet) and has the shape of “L,” for example. The shapes of the terminal portions 20b and 20c are optional.

A lead frame is used for the emitter electrode 20. The lead frame includes, for example, copper. For example, in the assembly process of the semiconductor device 1, the lead frame is cut and separated into a plurality of semiconductor devices 1. The cutting portion 20d of the lead frame of the emitter electrode 20 can be exposed from the side surface of the package. In the example shown in FIGS. 1 and 2, four cutting portions 20d project from both side surfaces of the package facing to the X direction. For example, in order to prevent the cutting portions 20d from coming into contact with a printed circuit board, another semiconductor device, or the like, a concave portion is provided on the side surface (package side surface) facing to the X direction of the sealing resin 10. The concave width W1 of the concave portion is greater than the amount of projection of the cutting portions 20d of the lead frame.

The two gate electrodes 30 function as terminals connected to external devices. The same lead frame as the emitter electrode 20 is used for the gate electrodes 30. The gate electrodes 30 project from near the central part of the side surface of the package facing to the Y direction (lower side of the drawing sheet) and extends in the Y direction (lower side of the drawing sheet). The two gate electrodes 30 are spaced apart from each other on both sides of the terminal portion 20b of the emitter electrode 20 in the X direction. In other words, one of the gate electrodes 30, the terminal portion 20b of the emitter electrode 20, and the other gate electrode 30 are arranged side by side in the X direction. The shape of the gate electrodes 30 projecting from the side surface of the package is approximately the same as that of the terminal portion 20b of the emitter electrode 20.

The collector electrode 40 is a plate-like heat sink component. The collector electrode 40 functions as a heat radiation plate. The exposed surface (bottom surface) of the collector electrode 40 is exposed from the bottom surface of the package. The exposed surface of the collector electrode 40 has flatness over the entire surface, for example. The exposed surface of the collector electrode 40 functions as a terminal connected to an external device. The shape of the exposed surface of the collector electrode 40 on the bottom surface of the package is optional. The exposed surface of the emitter electrode 20 and that of the collector electrode 40 face each other. The collector electrode 40 is formed of a conductive material and includes copper, for example.

The terminal portions (portions exposed from the sealing resin 10) of the emitter electrode 20, the gate electrodes 30, and the collector electrode 40 may be covered with tin (Sn), solder, and the like.

### 1.2 Internal Configuration of Semiconductor Device

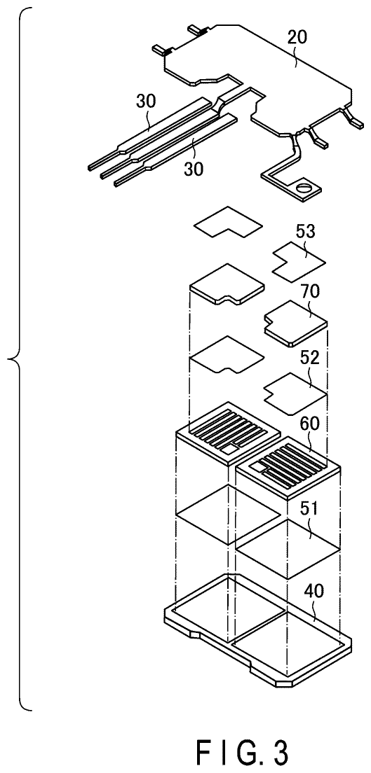

An example of an internal configuration of the semiconductor device 1 will be described below with reference to FIG. 3. FIG. 3 is an exploded view showing an example of the internal configuration of the semiconductor device 1. Specifically, FIG. 3 is a schematic view of the internal structure of the semiconductor device 1 that is separated into parts in the Z direction. Note that the sealing resin 10 is not shown in FIG. 3.

As shown in FIG. 3, the semiconductor device 1 includes, as its internal structure, two bonding materials 51, two semiconductor chips 60, two bonding materials 52, two spacers 70, and two bonding materials 53, in addition to the emitter electrode 20, the two gate electrodes 30, and the collector electrode 40.

The emitter electrode 20 is a conductor. The emitter electrode 20 is formed of a lead frame. The lead frame has a uniform thickness. The exposed portion 20a exposed from the top surface of the package, the terminal portions 20b and 20c projecting from the side surface of the package, and the cutting portion 20d projecting therefrom are different in height in the Z direction. Thus, the lead frame has bent portions for connecting the exposed portion 20a and each of the terminal portions 20b and 20c and cutting portion 20d. The bent portion is also referred to as a hanging pin because the exposed portion 20a is lifted upward by the bent portion from the substrate surface of the lead frame (the terminal portions 20b and 20c, and cutting portion 20d). As shown in FIG. 1, part of the hanging pin may be seen from the top surface of the package. Hereinafter, this structure of the lead frame will also be referred to as a hanging pin structure.

The two gate electrodes 30 are conductors. Since the two gate electrodes 30 are formed of the same lead frame as the emitter electrode 20, the thickness of each of the gate electrodes 30 is the same as that of the emitter electrode 20. The two gate electrodes 30 are arranged side by side with the terminal portion 20b that extends from the side surface of the emitter electrode 20. The two gate electrodes 30 are electrically connected to their respective pads corresponding to the gates of the two semiconductor chips 60.

The collector electrode 40 is a conductor. The collector electrode 40 is, for example, a copper plate that is thicker than the lead frame (the emitter electrode 20 and the gate electrodes 30). The bottom surface of the collector electrode 40 is exposed from the bottom surface of the package. On the top surface of the collector electrode 40, the two bonding materials 51 are provided apart from each other. The bonding materials 51 are, for example, plate-like solder. Each of the bonding materials 51 is provided between the collector electrode 40 and its corresponding semiconductor chip 60. Note that a groove for preventing solder from flowing may be formed in the top surface of the collector electrode 40 to surround the bonding materials 51.

The semiconductor chips 60 are, for example, a power semiconductor chip. Specifically, the semiconductor chip 60 is an insulated gate bipolar transistor (IGBT), a metal-oxide-silicon field-effect transistor (MOSFET) using silicon carbide (SiC), or the like. Note that if the semiconductor chips 60 are each a MOSFET using SiC, the emitter electrode 20 and the collector electrode 40 can be read as a source electrode and a drain electrode, respectively.

The bottom surface of each of the semiconductor chips 60 is used as an electrode corresponding to the collector. The bottom surface of each of the semiconductor chips 60 is electrically connected to the collector electrode 40 via its corresponding bonding material 51. For example, the area of the bottom surface of each of the semiconductor chips 60 is equal to or smaller than that of the groove formed in the collector electrode 40. A pad corresponding to the emitter and a pad corresponding to the gate are provided on the top surface of each of the semiconductor chips 60.

A bonding material 52 is provided in an area of the top surface of each of the semiconductor chips 60, the area including the pad corresponding to the emitter and excluding the pad corresponding to the gate. The bonding material 52 is, for example, plate-like solder. The pad corresponding to the gate on the top surface of each of the semiconductor chips 60 is electrically connected to its corresponding gate electrode 30 via wire (not shown).

On the top surface of each of the bonding materials 52, its corresponding spacer 70 is provided. The spacer 70 is a plate of a conductor. The conductor is, for example, copper.

On the top surface of each of the spacers 70, its corresponding bonding material 53 is provided. The bonding material 53 is, for example, plate-like solder. The bonding material 53 is provided between the spacer 70 and the exposed portion 20a of the emitter electrode 20. The pad corresponding to the emitter of each of the semiconductor chips 60 is electrically connected to the emitter electrode 20 with the bonding material 52, the spacer 70, and the bonding material 53 therebetween.

At the inside of the semiconductor device 1, three terminals used for input and output of the semiconductor chips 60 are electrically connected to their respective emitter electrode 20, gate electrode 30, and collector electrode 40. The bonding materials 51 to 53 and the spacers 70 are responsible for electrical connection between the semiconductor chips 60 and the terminals (electrodes), and have a function of radiating heat, which is generated in the semiconductor chips 60, to the emitter electrode 20 and the collector electrode 40 which function as heat sinks.

In FIG. 3, two semiconductor chips 60 are provided in the semiconductor device 1. However, the number of semiconductor chips 60 provided in the semiconductor device 1 may be one or three or more.

### 1.3 Planar Layout of Semiconductor Chip

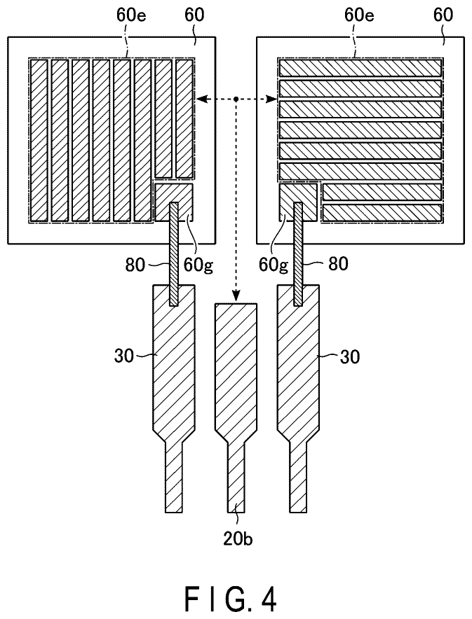

An example of a planar layout of the semiconductor chips 60 will be described below with reference to FIG. 4. FIG. 4 is a plan view showing an example of a planar layout of the semiconductor chips 60, the gate electrodes 30, and the terminal portion 20b of the emitter electrode 20. Note that other members (the sealing resin 10, the collector electrode 40, the bonding materials 51 to 53, and the spacer 70) of the semiconductor device 1 and other portions (20a, 20c, 20d) of the emitter electrode 20 are omitted from the example of FIG. 4.

As shown in FIG. 4, a pad 60e corresponding to the emitter and a pad 60g corresponding to the gate are provided on the top surface of each of the semiconductor chips 60.

The pad 60e is divided into a plurality of rectangular pads. The pad 60e is electrically connected to the emitter electrode 20.

The pad 60g has a rectangular shape, for example. The pad 60g is connected to its corresponding gate electrode 30 via wire 80.

### 1.4 Sectional Shape of Semiconductor Device

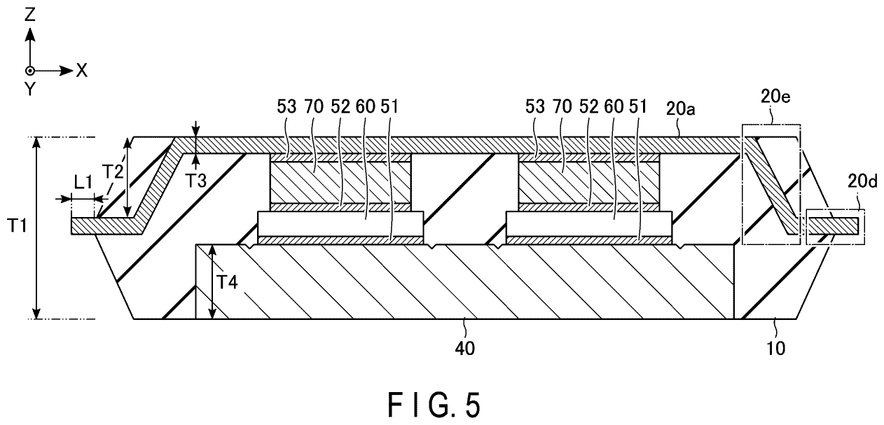

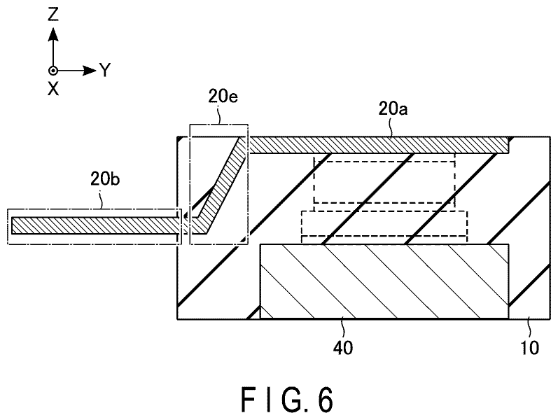

An example of the sectional shape of the semiconductor device 1 will be described below with reference to FIGS. 5 and 6. FIG. 5 is a sectional view of the semiconductor device 1 taken along line A-A of FIG. 1. FIG. 6 is a sectional view of the semiconductor device 1 taken along line B-B of FIG. 1.

As shown in FIG. 5, the bottom surface of the collector electrode 40 is exposed from the bottom surface of the sealing resin 10. On the top surface of the collector electrode 40, two semiconductor chips 60 are provided side by side in the X direction with two bonding materials 51 therebetween.

On the top surface of each of the semiconductor chips 60, the spacer 70 is provided with the bonding material 52 therebetween. The top surface of the spacer 70 is connected to the bottom surface (depressed surface) of the emitter electrode 20 with the corresponding bonding material 53 therebetween.

As shown in FIGS. 5 and 6, the thickness of the emitter electrode 20, that is, the lead frame, is uniform. The emitter electrode 20 further includes a plurality of bent portions (hanging pins) 20e which are provided in the sealing resin 10. The bent portions 20e are used to connect the portion 20a exposed from the top surface of the package of the emitter electrode 20 to the terminal portions 20b and 20c and the cutting portion 20d projecting from the side surface of the package. Assume that the height of the sealing resin 10 (package) in the Z direction is T1, the height of the bent portion 20e is T2, and the thickness of the emitter electrode 20 (and gate electrode 30) is T3. For example, the height T2 is equal to or higher than T3 and equal to or lower than T1-T3. In other words, the height of the terminal portions 20b and 20c and the cutting portion 20d from the bottom surface of the package is equal to or higher than T3 and equal to or lower than T1-T3 due to the bent portion 20e. That is, the projection positions of the terminal portions 20b and 20c and the cutting portion 20d from the side surface of the package are higher than the thickness of the emitter electrode 20 from the bottom surface of the package and lower than the thickness of the emitter electrode 20 from the top surface of the package. This can prevent the terminal portions 20b and 20c from being brought into contact with the external terminal or the like connected to the exposed portion 20a or the collector electrode 40. Similarly, the height of the gate electrode 30 placed side by side with the terminal portion 20b from the bottom surface of the package is equal to or higher than T3 and equal to or lower than T1-T3.

Assume that the thickness of the collector electrode 40 is T4. Thickness T3 is thinner than thickness T4 (T3<T4). If, therefore, the emitter electrode 20 and the collector electrode 40 are made of the same material, the rigidity of the emitter electrode 20 is lower than that of the collector electrode 40.

Assume that the length (projection amount) of the cutting portion 20d of the emitter electrode 20 projecting from the sealing resin 10 is L1. The concave width W1 of the concave portion of the side surface of the package, which have been described with reference to FIG. 1, is greater than the length L1 (W1>L1).

### 2. Method for Manufacturing Semiconductor Device

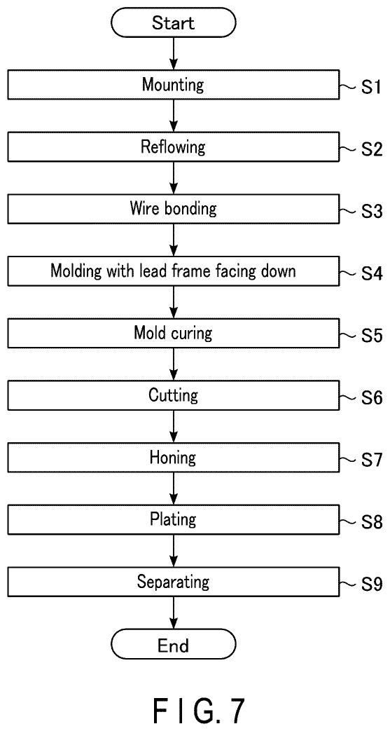

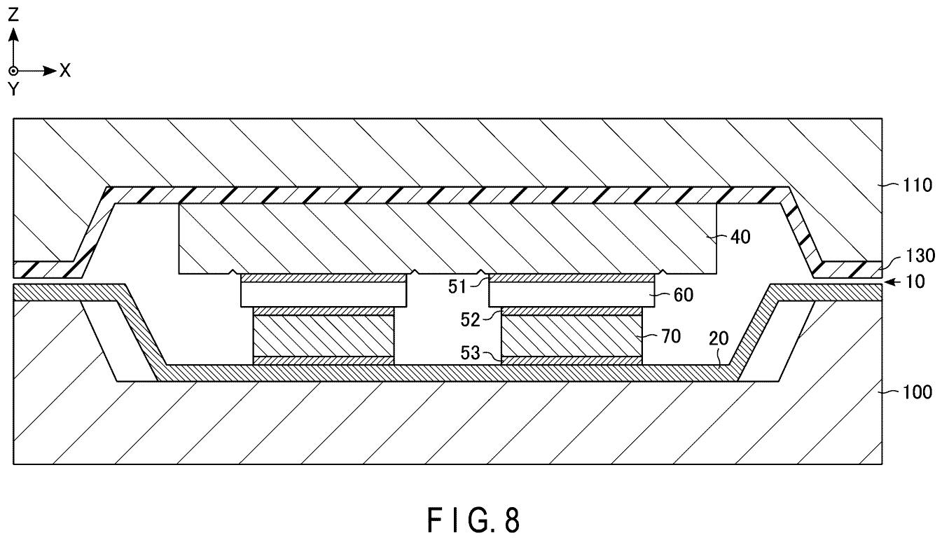

An example of a method for manufacturing the semiconductor device 1 will be described below with reference to FIGS. 7 and 8. FIG. 7 is a flowchart showing an example of an assembly process of the semiconductor device 1. FIG. 8 is a sectional view showing an example of a state in which a wire bonding product of the semiconductor device 1 is set in a mold for molding.

As shown in FIG. 7, first, each component described with reference to FIG. 3 is mounted (S1). More specifically, for example, the bonding materials 53, the spacer 70, the bonding materials 52, the semiconductor chips 60, the bonding materials 51, and the collector electrode 40 are mounted in sequence on the lead frame (including the emitter electrode 20 and the gate electrode 30) which has not been separated.

Then, reflow is executed (S2) to cause the bonding materials 51 to 53, i.e., solder to be melted and thus cause the lead frame (emitter electrode 20), the spacer 70, the semiconductor chips 60, and the collector electrode 40 to be bonded. In steps S1 and S2, the solder assembly of the semiconductor device 1 is completed.

Then, wire bonding is performed (S3). That is, a wire bonding product is formed. More specifically, a pad corresponding to the gate of the semiconductor chip 60 and the gate electrode 30 are connected by wire 80.

Then, molding (sealing process) is performed (S4) in which the wire bonding product of the semiconductor device 1 is sandwiched by a mold with the lead frame facing down. A case where transfer molding is performed will be described below. More specifically, as shown in FIG. 8, the wire bonding product of the semiconductor device 1 is set on a lower mold 100 with the lead frame facing down. In this case, the lead frame is directly pressed against the lower mold 100. Since the lead frame is thinner and less rigid than the collector electrode 40, a gap between the lead frame and the lower mold 100 is less likely to be formed than when the collector electrode 40 is placed on the lower side. For example, a protective film 130 is provided on the inner surface of an upper mold 110. The collector electrode 40 is in contact with the protective film 130. In this state, the sealing resin 10 is poured and temporarily cured.

Then, mold curing is performed (S5). For example, a thermosetting resin is used as the sealing resin 10. The sealing resin 10 is fully cured by the curing. In steps S4 and S5, the molding is completed.

Then, cutting is performed (S6) to shave the exposed surface (bottom surface of the package) of the collector electrode 40. Thus, the top and bottom surfaces of the package are made parallel.

Then, honing is performed (S7) to deburr the sealing resin 10. In the present embodiment, molding is performed with the lead frame pressed against the lower mold 100. Thus, burrs on the contact surface of the lead frame with the lower mold 100, that is, on the top surface of the package, are reduced. Incidentally, the protective film 130 suppresses burrs from occurring on the bottom surface (the exposed surface of the collector electrode 40) of the package.

Then, the exposed surfaces of the lead frame (the emitter electrode 20 and the gate electrode 30) and the collector electrode 40, which are exposed from the sealing resin 10, are plated. The plating is electroplating. Electrodes for plating are brought into contact with both the collector electrode 40 and the lead frame.

Then, separation is performed to cut the semiconductor device 1 from the lead frame. At this time, the two gate electrodes 30 are also separated.

With the configuration according to the present embodiment, the manufacturing costs of a semiconductor device 1 can be decreased.

If, in the semiconductor device 1, the height position of the exposed surface (the top surface of the package) of the emitter electrode in the Z direction differs from that of the terminal portion projecting from the side surface of the package in the Z direction, a lead frame having multi-gauge strips is used in which the thickness of the exposed portion differs from that of the terminal portion. The product costs of the lead frame having multi-gauge strips are higher than that of a lead frame having a uniform thickness. In addition, the lead frame having multi-gauge strips increases in its thickness and thus improves in its rigidity. If, therefore, the lead frame is tilted, warped, or the like during molding, a gap is likely to be formed between the lead frame and the lower mold for molding. Accordingly, a sealing resin adheres onto the exposed surface. It is thus necessary to remove the sealing resin, which complicates deburring and increases manufacturing costs.

In contrast, in the configuration according to the present embodiment, the exposed portion 20a of the emitter electrode 20 is connected to the terminal portions 20b and 20c and the cutting portion 20d via the bent portion 20e. Thus, the exposed portion 20a, terminal portions 20b and 20c, and the cutting portion 20d can change their heights in the Z direction in the package. In other words, the hanging pin can hold the exposed portion 20a at a different height from the terminal portions 20b and 20c and the cutting portion 20d. A lead frame having a uniform thickness can thus be used for the emitter electrode 20. Therefore, the cost of the lead frame can be reduced as compared with the case of using a lead frame having multi-gauge strips.

Furthermore, in the configuration according to the present embodiment, the rigidity can be kept low by using a thin lead frame having a uniform thickness. In molding, the lead frame is placed on the lower side and pressed against the lower mold 100, so that a gap between the lower mold 100 and the lead frame is hardly generated. Thus, burrs can be reduced on the contact surface of the lead frame with the lower mold 100, that is, on the top surface of the package. Since, therefore, resin burrs can be removed by honing, the manufacturing costs of the assembly process can be reduced.

### 3. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip;
a first conductor including:
a first portion exposed from a first surface of a sealing resin facing to a first direction;
a second portion projecting from a second surface of the sealing resin facing to a second direction intersecting with the first direction; and
a bent portion connecting the first portion and the second portion;
a second conductor exposed from a third surface of the sealing resin opposed to the first surface and having a thickness in the first direction which is greater than a thickness of the first conductor;
a third conductor provided between the semiconductor chip and the first conductor;
a first bonding material which bonds the semiconductor chip and the second conductor;
a second bonding material which bonds the semiconductor chip and the third conductor; and
a third bonding material which bonds the third conductor and the first conductor.

2. The semiconductor device according to claim 1, wherein the first conductor is formed by a lead frame and has a uniform thickness.

3. The semiconductor device according to claim 1, further comprising a fourth conductor which projects from the second surface of the sealing resin, which is located side by side with the second portion of the first conductor in a third direction intersecting with the first direction and the second direction, and which is electrically connected to the semiconductor chip.

4. The semiconductor device according to claim 3, wherein
an emitter of the semiconductor chip is electrically connected to the first conductor,
a collector of the semiconductor chip is electrically connected to the second conductor, and
a gate of the semiconductor chip is electrically connected to the fourth conductor.

5. The semiconductor device according to claim 1, wherein:
the first conductor further includes a third portion projecting from a concave portion of a fourth surface of the sealing resin facing to a third direction intersecting with the first direction and the second direction; and
the concave portion has a width that is greater than an amount of projection of the third portion.

6. The semiconductor device according to claim 1, wherein a position of projection of the second portion from the second surface is higher than a thickness of the first conductor from the third surface and lower than the thickness of the first conductor from the first surface in the first direction.

7. A method for manufacturing a semiconductor device comprising:
forming a solder assembly product including a semiconductor chip, a first conductor, a second conductor that is thicker than the first conductor, a third conductor provided between the semiconductor chip and the first conductor, a first bonding material which bonds the semiconductor chip and the second conductor, a second bonding material which bonds the semiconductor chip and the third conductor, and a third bonding material which bonds the third conductor and the first conductor;
forming a wire bonding product;
molding the wire bonding product set between a lower mold and an upper mold with the first conductor facing down; and
cutting the first conductor.

8. The method according to claim 7, wherein the first conductor includes:
a first portion exposed from a first surface of a sealing resin facing to a first direction;
a second portion projecting from a second surface of the sealing resin facing to a second direction intersecting with the first direction; and
a bent portion connecting the first portion and the second portion.

9. The method according to claim 7, wherein the first conductor is formed by a lead frame and has a uniform thickness.

10. The method according to claim 7, further comprising connecting the semiconductor chip with a fourth conductor by wire.

11. The method according to claim 7, wherein the molding includes providing a film between the upper mold and the wire bonding product.
